(19) United States
(12) Patent Application Publication
(10) Pub. No.: US 2004/0120259 A1
(43) Pub. Date: Jun. 24, 2004

(54) Passive network tap device

(76) Inventors: Stewart Jones, Colorado Springs, CO (US); Alistair Scott, Colorado Springs, CO (US); Douglas Carson, Edinburgh (GB); Mark H. Copley, Colorado Springs, CO (US)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/327,552

(22) Filed: Dec. 20, 2002

(51) Int. Cl. G01R 31/08

(52) U.S. Cl. 370/250; 370/246

(57) ABSTRACT

A tap device comprises a network entry connection, a network exit connection, and a network interconnection path there between. A high impedance tap circuit is electrically connected to the network connection path, and comprises an isolation transformer and active buffer element. Advantageously, a power interruption to said tap circuit does not affect network communications.

### BACKGROUND

A LAN tap device is used as part of a testing/monitoring system to eavesdrop onto a LAN network without disturbing the function of the network. As the tap eavesdrops, it collects and analyzes traffic on the network to provide information related to the operational efficiency and performance of the network and measures parameters such as signaling and voice quality. This collected information assists service providers in offering consistent and high quality network services to its customers. Tap devices may be placed anywhere along a length of communication wire that comprises the network. Accordingly, it is important that the tap device performance not be affected by placement on the network. Similarly, it is important that the tap device permit normal operation of the network being monitored. The tap electronics are typically placed in series with network communication wires. Because the communication wire can be quite long in some cases, the tap device is not always co-located with a network source or destination switch. If a power interruption to the tap device occurs, it is desirable that the network remains fully operational.

With specific reference to FIG. 1 of the drawings, there is shown a representative tap circuit that is part of a prior art tap device that is placed in series with a network communication wire 101. The tap circuit comprises two series high impedance buffers 102, 105 connected in parallel with a switch 103. A monitoring signal 104 is extracted from the output of a first one of the high impedance buffers 102. The tap circuit electrically connects a first and second portion of the network communications wire 101. In the event of a power interruption, either a surge or a loss of power, the high impedance driver circuit 102 fails to operate and the switch 103 closes to complete a circuit with the first and second portions of the communication wire 101. Advantageously, this design completes the communication wire circuit in the event of a power interruption. Disadvantageously, however, this design can cause a disruption in the network. There can be a delay between the time the buffers 102 and 105 are no longer powered, and do not operate properly, and the time the switch closes in a stable condition. This delay can be significant enough to cause the network link to break. Because the switch 103 is a mechanical device, as it closes, it may exhibit chatter before settling to its completely closed position. A typical timeframe for a mechanical switch to completely close can be 1-2 msec. If the network link is broken as a result of the delay, the network must re-synchronize to re-establish the broken link. Re-synchronization typically uses a spanning tree algorithm and may take up to 30 seconds to regain an operational link. In a high-availability network, the potential for a 30 second disruption is undesirable. There is a need, therefore, for a tap device that does not disturb the network in the event of a power interruption.

### SUMMARY

A LAN tap comprises a network entry connection, a network exit connection, and a network connection path there between. A tap circuit is electrically connected to the network connection path, and comprises an isolation transformer and active buffer element.

In another embodiment according to the teachings of the present invention a LAN tap comprises a first tap electrically connected to a first interconnection path, a second tap electrically connected to a second interconnection path, a buffer amplifier having an input end and an output end and an isolation transformer having an input side and an output side, said input side connected to said first and second taps and said output side connected to said input end of said buffer amplifier.

According to another aspect of the present invention, an apparatus for eavesdropping onto a data network comprises an input port having at least first and second input interconnection points, an output port having at least first and second output interconnection points, and first and second interconnection paths between the first input interconnection point and the first output interconnection point, and the second input interconnection point and the second output interconnection point, respectively. A first tap is electrically connected to said first interconnection path and a second tap is electrically connected to said second interconnection path. An isolation transformer has first and second primary winding ends and first and second secondary winding ends. The first tap is connected to the first primary winding end and the second tap is connected to the second primary winding end. A buffer has positive and negative input connections and an output end. The first secondary winding end is connected to the positive input connection and the second secondary winding end is connected to the negative input connection.

According to another aspect of the present invention, a method for insuring uninterrupted operation of a monitored network comprises the steps of connecting a first tap device to the monitored network, the first tap device comprising a chassis, a power supply, a rear transition module and an aggregator. The method further comprises the steps of monitoring the network through the first tap device, removing power from the first tap device, and removing the rear transition module from the first tap device. The method continues with the steps of installing the rear transition module into a second tap device, the second tap device comprising a second chassis, a second power supply and a second aggregator, powering the second tap device, and monitoring the network through the second tap device.

Advantageously, certain embodiments of a tap device and eavesdrop apparatus according to the teachings of the present invention permit uninterrupted network function in the event of a power outage or other disruption to the tap device. In addition, certain embodiments of a tap device and eavesdrop apparatus according to the teachings of the present invention may be placed anywhere along a network without compromise to the network signals.

### BRIEF DESCRIPTION OF THE FIGURES

FIG. 1 is a circuit diagram of an illustrative circuit for a tap device according to prior art.

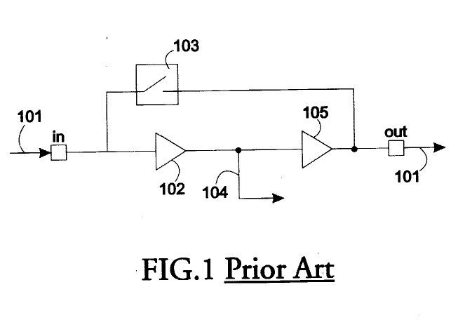

FIG. 2 is a diagram of a rear panel of an embodiment of a tap device according to the teachings of the present invention illustrating a single network connection.

FIG. 3 is a diagram of a front panel of an embodiment of a tap device according to the teachings of the present invention.

FIG. 4 is a block diagram showing a relationship of multiple network connections, tap signals, and a network signal aggregator.

FIG. 5 is a representation of connections between an input port and an output port in an embodiment of a tap device according to the teachings of the present invention.

FIG. 6 is a block diagram of an embodiment of a tap interface according to the teachings of the present invention.

FIG. 7 is a circuit diagram of an embodiment of a tap device circuit according to the teachings of the present invention.

FIG. 8 is a flow chart of commands issued to a network switch in an embodiment of a tap device according to the teachings of the present invention to perform a signal aggregation function.

FIG. 9 is a flow chart of an embodiment of a method according to the teachings of the present invention.

### DETAILED DESCRIPTION

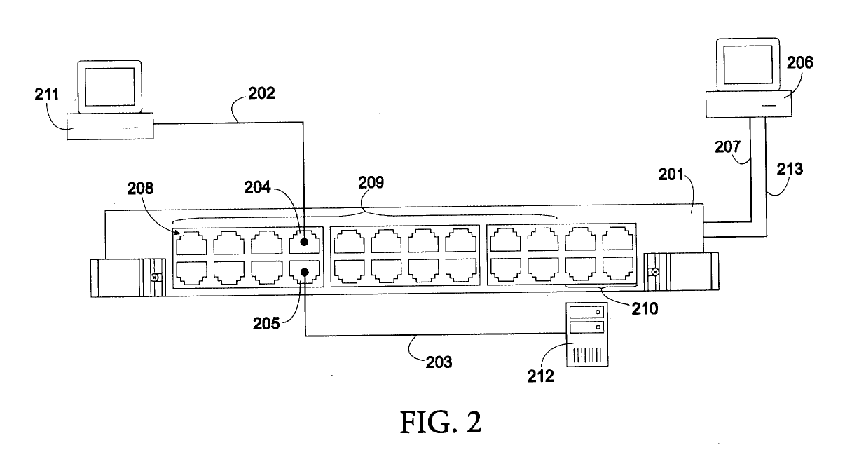

With specific reference to FIG. 2 of the drawings, there is shown a diagram of rear panel of an embodiment of a tap device 201 according to the teachings of the present invention. The tap device 201 has a total of twenty-four data ports 208. For purposes of clarity, only a subset of the data ports 208 has reference numbers. Twenty of the data ports 208 comprise monitoring data ports 209, which are configured in the tap device 201 for a monitoring function. The remaining four data ports 208 are switched data ports 210 and are not configured for the monitoring function, but are configured as standard switched Ethernet data ports. The monitoring data ports 209 are logically grouped in pairs, with each pair being connected to a network 202, 203 in which the tap device 201 has an entry connector 204 for establishing a network entry connection and an exit connector 205 for establishing a network exit connection. In the illustration of FIG. 2 of the drawings, the network is represented as a communication link between a first networked element 211 and a second networked element 212. The first and second networked elements 211 and 212 are represented as a computer and a network switch, respectively, but could be any device that is able to communicate on a network. A first communications wire 202 connects the first networked element 211 to the tap device 201 through the entry connector 204 and a second communications wire 203 connects the tap device 201 through the exit connector 205 to the second networked element 212. Accordingly, a network link is represented as two communications wires 202, 203, which but for the tap device 201, would normally be an unbroken single wire. For purposes of clarity, only one connection is shown. In a more practical embodiment, all of the monitoring data ports 209 are populated with up to a total of ten network connections. In a specific embodiment of the tap device 201, network data from ten of the data ports 209 are aggregated onto a first monitoring data link 207 and the network data from the remaining ten data ports 209 are aggregated onto a second monitoring data link 213. In a specific embodiment, the first and second monitoring data links 207, 213 are fiber optic cables, each cable carrying a 1 Gbps signal. The aggregated data on the first and second monitoring data links 207, 213 are transmitted to a monitoring processor 206 for analysis.

In a specific embodiment, the tap device is based upon a CPC4401 from Performance Technologies, Inc. The CPC4401 comprises a data switch and a rear transition module. In a specific embodiment, the rear transition module that is a standard commercial product that comes with the CPC4401 is replaced with circuitry according to the teachings of the present invention. For purposes of simplicity, an embodiment of the circuitry according to the teachings of the present invention is disposed on a printed circuit board having the same form factor as the standard rear transition module that comes with the CPC4401. The replacement circuitry accepts and passes through first and second transmit signals present on the up to the 10 full-duplex data port pairs while aggregating the signals from the up to 10 network connections onto the two monitoring data links 207, 213.

The monitoring processor 206 comprises a Windows NT workstation with a PCI (TM) backplane interface in which an ENP2506-P Dual GigaBit EthernetHSPP monitoring printed circuit board is plugged. The monitoring processor board is an IXP 1200 based high-speed network processor card with two physical gigabit interfaces (IEEE 802.3× and IEEE802.3z compliant). The monitoring processor board performs optimally in a 64-bit, 66 MHz PCI slot, but also works in a 32-bit 33 MHz slot. Although only one network connection is shown in FIG. 2, in a specific embodiment, up to ten different full-duplex network connections may be made to the tap device 201. The ten signals are aggregated within the tap device 201 and are launched onto the monitoring signal data links 207, 213 for analysis by the monitoring processor 206.

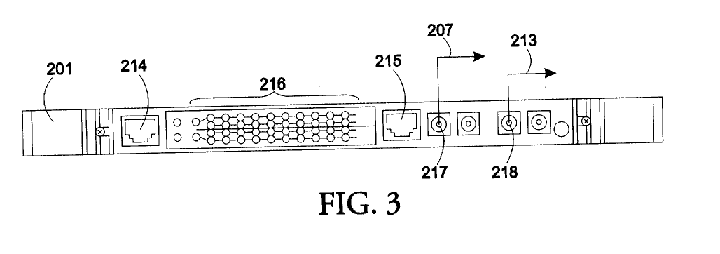

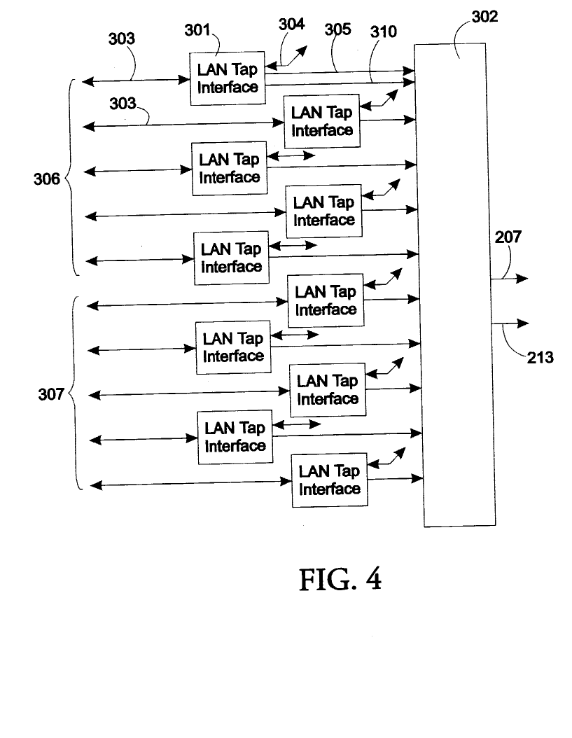

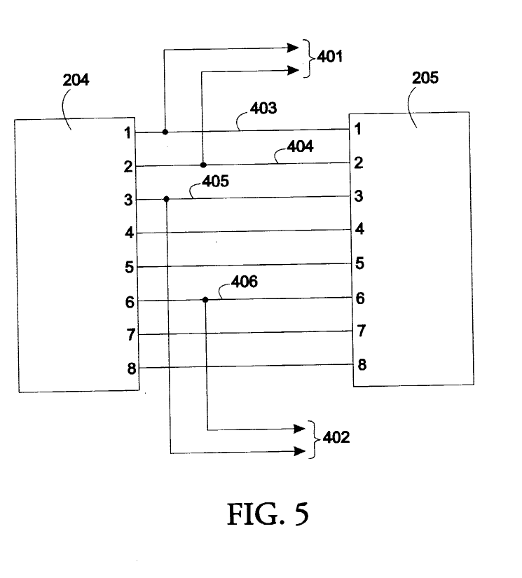

With specific reference to FIG. 3 of the drawings, there is shown a front panel of a tap device 201 according to the teachings of the present invention. An RS-232 management port 214 permits programming of the tap device 201. An Ethernet management port 215 also permits programming, but not until the port 215 is configured with an IP address through the RS-232 management port 214. Accordingly, for purposes of the present teachings, it is simplest to use the RS-232 management port 214 exclusively, although variants obvious to one of ordinary skill may have a need for programming through the Ethernet management port 215. A panel of indicators 216 provides status information related to status and activity for each network connection made to the tap device 201. The tap device 201 also comprises first and second Gigabit fiber optic Ethernet ports 217, 218. The first and second monitoring data links 207, 213 are connected to the first and second Gigabit fiber optic Ethernet ports 217, 218, respectively, to accomplish the interconnection of the tap device 201 and the monitoring processor 206. With specific reference to FIG. 4 of the drawings, there is shown a block diagram of a structure with ten tap interfaces 301 and aggregator 302 according to the teachings of the present invention in which ten 100BaseT Ethernet network connections 303 are made to the tap device 201. In a specific embodiment of the tap device 201, signals present on a first bank of data port pairs 306 are aggregated onto the first monitoring data link 207. Signals present on a second bank of data port pairs 307 are aggregated onto the second monitoring data link 213. Each network connection is a full-duplex connection. Because the tap device is a monitoring solution, and is placed in a position between the two networked elements 211, 212, the communication signals are referred to as a first and second transmit signals. The first transmit signal is transmitted by the first networked element 211 and is received by the second networked element 212. Similarly, the second transmit signal of is transmitted by the second networked element 212 and is received by the first networked element 211. Accordingly, it is the two signals transmitted by the first and second networked elements 211, 212 that are sampled and aggregated by the tap device 201 and monitored by the monitoring processor 206. Each tap interface 301 comprises two tap circuits, a first transmit tap circuit and a second transmit tap circuit. For purposes of clarity, only one 100BaseT connection circuit is described, but there are twenty circuits total, ten first transmit tap circuits and ten second transmit circuits, in a tap device that monitors up to 10 network connections. Each signal wire shown in FIG. 4 comprises a first transmit and second transmit signal pair, where each signal pair carries a differential signal. The tap interface 301 contains two tap circuits, each tap circuit comprising a through interconnection resulting in a first exit signal pair 304 as well as a tap resulting in a second single-ended exit signal pair 305 and 310. Accordingly, there are a total of four exit signals; two differential exit signals based upon the first transmit signal and the second transmit signal and two single-ended exit signals 305, 310 based upon the first and second transmit signal pairs, respectively. A first signal path presents an electrical through connection so that the first exit signal wire pair 304 carries substantially the same signal present on the entry signal wire pair 303. Accordingly, the first exit signal wire pair 304 may be connected back into the network without compromising the integrity of the signal present. A second signal path presents a tap circuit wherein a portion of the entry signal is sampled and launched onto the second exit signal wire 305 or 310. The second exit signal wires 305, 310 are two inputs of a plurality of inputs, ten in the illustrated embodiment, to the aggregator 302. The aggregator 302 accepts network data from the second exit signal wires 305, 310 in the form of packets and multiplexes the packets from a first bank 306 of ports, onto the first Gigabit fiber optic Ethernet port 207. As one of ordinary skill in the art can appreciate, both the first and second transmit signals from the first bank 306 are aggregated onto the first monitoring data link 207. Similarly, both the first and second transmit signals from a second bank 307 of ports are aggregated onto the second monitoring data link 213 With specific reference to FIG. 5 of the drawings, there is shown a representation of connections between one of the entry connectors 204 and a corresponding one of the exit connectors 205. All ten of the entry/exit connector pairs have a similar structure. Accordingly, discussion is limited to the structure of just one pair. In a specific embodiment, the entry and exit connectors 204, 205 are RJ45 connectors having a total of 8 connector pins. Each of the 8 pins of the entry connector 204 is directly connected to a respective one of the 8 pins of the exit connector 205. In a specific embodiment, pins 1 and 2 comprise a first transmit signal pair 401 and pins 3 and 6 comprise a second transmit signal pair 402. A monitoring connection is made to each of the four wires that comprise the receive and transmit signal pairs 401, 402 to perform the eavesdropping function. The connection between respective ones of the four pins of the entry and exit connectors 204, 205, however, are pure through network interconnection paths. The remaining pins of the respective entry and exit connectors 204, 205 are a pure through connection and do not have a monitoring connection.

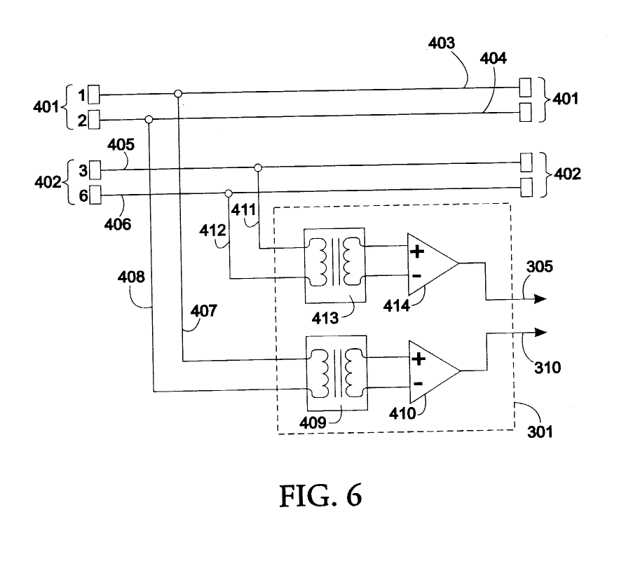

With specific reference to FIG. 6 of the drawings, there is shown a block diagram of the first and second transmit signal wire pairs 401, 402, respectively, and the network interconnections paths 403/404 and 405/406, respectively. Each first and second transmit signal wire pair 401, 402 for example, are part of a single network connection made with the entry and exit connectors 204, 205. In the differential signal embodiment shown, a first transmit high network interconnection path 403 and a first transmit low network interconnection path 404 electrically connect the first transmit signal wire pair 401 portion of the entry connector 204 to the first transmit signal wire pair 401 portion of the exit connector 205. Similarly, a second transmit high network interconnection path 405 and a second transmit low network interconnection path 406 electrically connect the second transmit signal wire pair 402 portion of the entry connector 204 to the second transmit signal wire pair 402 portion of the exit connector 205. A first transmit high tap 407 and a first transmit low tap 408 connect to the first transmit high interconnection path 403 and the first transmit low interconnection path 404, respectively. The first transmit high tap 407 is connected to a first end of a primary winding of a 1:1 isolation first transmit transformer 409, and the first transmit low tap 408 is connected to a second end of the primary winding of the first transmit transformer 409. The secondary windings of the first transmit transformer 409 are connected to a first transmit buffer element 410. The tap interface 301 further comprises a parallel structure for the transmit signal wire pair 402 wherein a second transmit high tap 411 and a second transmit low tap 412 connect to the second transmit high interconnection path 405 and the second transmit low interconnection path 406, respectively. The second transmit high tap 411 is connected to a first end of a primary winding of a 1:1 isolation second transmit transformer 413, and the second transmit low tap 412 is connected to a second end of the primary winding of the second transmit transformer 413. The secondary windings of the second transmit transformer 414 are connected to a second transmit buffer element 414. Outputs of the first and second transmit buffer elements 410, 414 comprise the monitoring signals 305 310. Because the tap connections are sufficiently high impedance and are isolated from the tap circuitry by the isolation transformers, the loss of power to the buffer elements in the tap interface 301 do not drastically change the relative impedance between the tap interface and the network interconnection paths 403-406. The network interconnection paths 403-406 are low impedance direct and passive connections. When power fails at the tap device 201, the first and second transmit network interconnection paths 403-406 remain uninterrupted permitting normal and consistent network functions. Additionally, when power to the tap device 201 fails, the buffer elements 414, 410 cease to operate. When the buffer elements no longer have power, they present a high impedance at their inputs. In a specific embodiment if there is a loss of power to the tap device, the initial high impedance buffer characteristics coupled with passive transformer coupling of the signals permits the network interconnection path to remain in tact regardless of the power loss.

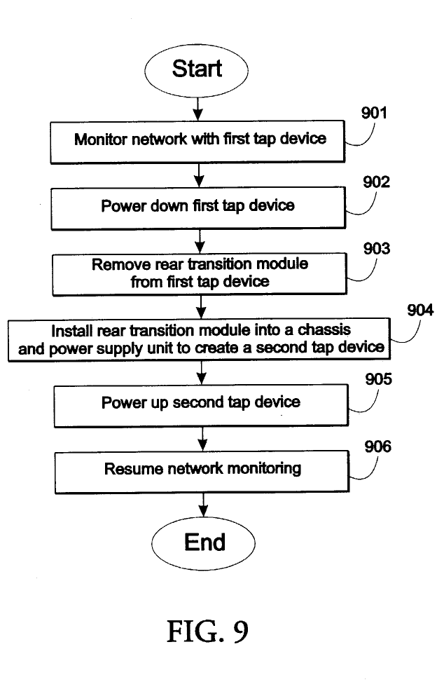

With specific reference to FIG. 9 of the drawings, to extend this concept, it is also an advantage that a rear transition module in an embodiment of a tap device 201 according to the teachings of the present invention may be unplugged from the tap device 201 without affecting network operations. Specifically, at sometime during monitoring of a network 901, the tap device 201 may be powered down 902. As described, this power down process does not affect the network that the tap device 201 is monitoring. After power down, the rear transition module, which houses the tap circuitry and network interconnection paths 403/404 and 405/406, may be removed 903 from the tap device 201 without affecting the network connected thereto. This is due to the fact that there is a direct network interconnection path 403/404 and 405/406 that interconnects the entry and exit connectors 204, 205 and, therefore, the first and second communications wires 202, 203 (See FIG. 2 of the drawings). The unpowered rear transition module may then be installed 904 into a new or repaired chassis/power supply unit to create a second tap device 201, also without interruption to the network. The term “second tap device” refers to either a new tap device comprising a chassis, power supply, and aggregator or a repaired chassis/power supply and aggregator 302 from the original tap device 201. The concept being that all parts of the tap device 201 including the chassis, the power supply and the aggregator 302 may be powered down, removed, and re-connected without interruption to the monitored network. Power may then be restored 905 to the new or re-connected tap device 201 without affecting network operations and monitoring of the network via the tap device 201 and monitoring processor 206 may be resumed 906. This feature is helpful for high availability networks in the event of an equipment failure to a tap device chassis power supply, or aggregator 302 to permit repair and maintenance of the monitoring equipment without interrupting the monitored network.

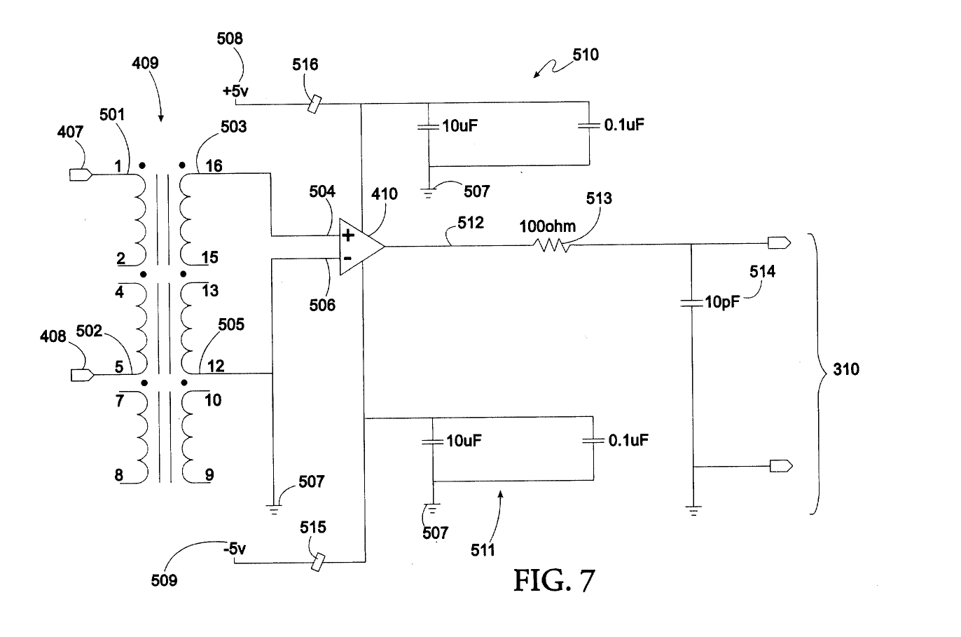

With specific reference to FIG. 7 of the drawings, there is shown a more detailed schematic drawing of a first transmit tap circuit within the tap interface 301. A second transmit tap circuit., also part of the tap interface 301 is virtually identical in structure and is not specifically detailed. Accordingly, the “first” and “second” descriptive nomenclature to describe the tap circuits is dropped for purposes of describing FIG. 7 of the drawings. The first transmit high tap 407 connects to the first end 501 of a primary winding of the transformer 409. The transformer comprises a Pulse Engineering part no. 65733, which has 3 transformer elements in a single package. In order to obtain optimum inductance characteristics to better match the impedance characteristics of the signal pair 401, two of the three transformer elements are connected in series to create the transformer 409. The first transmit low tap 408 connects to the second end 502 of the primary winding of the transformer 409. The first end 503 of the secondary winding of the transformer 409 is connected to a positive input 504 of the buffer element 410. The second end 505 of the secondary winding of the transformer 409 is connected to a negative input 506 of the buffer element 410 as well as reference potential 507. Advantageously, the high impedance nature of the input buffering through the transformer connection provides for minimal impact on the network signal quality regardless of where the tap device is placed along the network. The connection structure of the monitoring signal through the transformer converts the differential signal of the network to a single-ended signal within the tap interface 301. In a specific embodiment, the buffer element 410 is powered by +/−5 volt power signals 508, 509 filtered by respective capacitive networks 510, 511 according to buffer element convention. In a specific embodiment, the buffer element 410 amplifies the incoming signal by two times and launches the amplified signal onto buffer element output 512. Output resistor 513 is 100 ohms and is matched to an impedance of a monitoring signal wire 305 or 310, which in a preferred embodiment is also 100 ohms. This impedance match voltage divides the amplified signal back to its original level for presentation to the aggregator 302. A 10 picofarad output capacitor 514 is in parallel with the output resistor 513 to provide low pass filtering to improve the quality of the buffer output signal. A ferrite bead 515, 516 is disposed between the positive and negative bias voltage sources and the positive and negative bias connections to the buffer element 410. Capacitive bias circuits 510, 511 comprise a 10 microfarad capacitor in parallel with a 0.1 microfarad capacitor. A positive bias circuit 510 is disposed between the positive bias connection to the buffer element 410 and reference potential 507. A negative bias circuit 511 is disposed between the negative bias connection to the buffer element 410 and reference potential 507. The monitoring signal 305 or 310 is one of twenty such monitoring signals that are connected to the aggregator 302. The aggregator 302 concentrates the data from multiple network interfaces, ten in the specific example, onto a single higher data-rate interface. The aggregator comprises a CPC4401 network switch that is programmed to perform the aggregation function. Each pair of network ports is wired as a pass through connector as shown in FIG. 5 of the drawings so that is can be placed within the network without disturbing network is forwarded to the switching portion of the CPC4401.

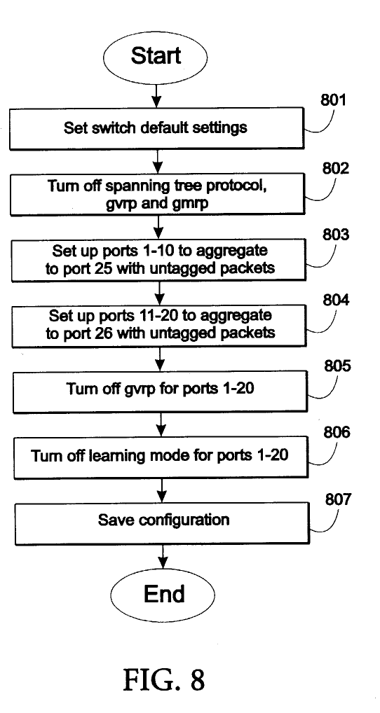

The switching portion of the CPC4401 is programmed to aggregate 10 of the monitoring signals 415 onto the first Gbps port 207 and a remaining ten of the monitoring signals onto the second Gbps port 213. With specific reference to FIG. 8 of the drawings there is shown a flow chart of an embodiment of instructions given to the switching portion of the CPC4401 to set up the aggregation function. Initially, the switch is programmed to return to its default factory settings 801. This is done so that the switch starts from a known and stable status. The spanning tree protocol, generic attribute registration protocol VLAN registration protocol (“gvrp”) and generic attribute registration protocol multicast registration protocol (“gmrp”) functions are then all disabled 802. Five virtual local area networks (“VLAN”) are then defined within the switch between a first five port pairs and a first Gigabit port 207 and five more VLANs are defined between the remaining port pairs and the second Gigabit port 213. In a specific embodiment, all VLANs are defined as untagged. Specifically, ports 1, 2, and 25 are set up 803 as VLAN #1. Similarly, ports 3, 4, and 25 are VLAN #2, ports 5, 6, and 25 are VLAN #3, 7, 8, and 25 are VLAN #4 and ports 9, 10, and 25 are VLAN #5. Accordingly, the first 10 ports, representing five networks, are aggregated to a transmit portion of Gigabit port #25 represented by reference number 207. Ports 11, 12, and 26 are set up 804 as VLAN #6, ports 13, 14, and 26 are set up as VLAN #7, ports 15, 16, and 26 are set up as VLAN #8, ports 17, 18, and 26 are set up as VLAN #9, ports 19, 20, and 26 are set up as VLAN #10. Accordingly, the second 10 ports representing five networks are aggregated to a transmit portion of Gigabit port #26 represented by reference number 213. An 11^{th} VLAN is set up for the remaining unused ports and are not matched to either monitoring port, ports 25 or 26 in the specific embodiment. The gvrp function is then turned off 805 for ports 1-20 to complete the disabling of the gvrp function. A learning option is then turned off 806 for ports 1-20 in order to force the forwarding of all packets to the Gigabit ports 207, 213. The programmed configuration is then saved 807. Because the configuration is saved in a flash memory, the tap device is appropriately programmed upon power-up.

In an alternate embodiment of programmed for the aggregator 301, port pairs are assigned to the monitoring ports on an alternating basis. For example, ports 1 and 2 are assigned to port 25 in a VLAN and ports 3 and 4 are assigned to port 26 in a VLAN. This configuration may be used to load balance traffic between the two monitoring ports.

In another alternate embodiment it may be desirable for the packets that make up the monitoring signal contain information as to their source. This is achieved by using the “tag” function when programming the switch. The tag function adds 2 bytes of information to each frame of data that is aggregated into the monitoring signal. Implementation of the alternate embodiment is similar to the process illustrated in FIG. 8 of the drawings, except that step 803 is programmed to set up the first 10 ports as VLAN pairs together with a tagged port 25. Specifically, ports 1, 2, and 25 are set up as VLAN #1 with ports 1 and 2 being untagged and port 25 being tagged. The same set up is repeated for ports 3 through 10. Similarly, step 804 is programmed to set up the second five ports as VLAN pairs together with a tagged port 26. Specifically, ports 11, 12, and 26 are set up as VLAN #6 with ports 11 and 12 being untagged and port 26 being tagged. The same set up is repeated for ports 13 through 20. Other programming alternatives using the VLAN function to aggregate data will occur to one of ordinary skill in the art with benefit of the present teachings.

Embodiments of the invention are described herein by way of example and are intended to be illustrative and not exclusive of all possible embodiments that will occur to one of ordinary skill in the art with benefit of the present teachings. Specifically, the teachings may be applied to any number of data ports. Other methods of data aggregation may be performed using different switch hardware and using different programming methods.

1. A tap device comprising:
a network entry connection,
a network exit connection,
a network interconnection path between said network entry connection and said network exit connection,
a tap circuit electrically connected to said network interconnection path, said tap circuit comprising an isolation transformer and active buffer element.

2. A tap device as recited in claim 1 said network entry and exit connections comprising differential signal connections and said tap circuit converts said differential signal connections to a single-ended signal connection.

3. A tap device as recited in claim 1 and further comprising a plurality of said network entry and exit connections having a respective said network connection path there between, a plurality of said tap circuits wherein an output of said buffer elements are aggregated.

4. A tap device as recited in claim 1 wherein said isolation transformer is a one to one transformer.

5. A tap device as recited in claim 1 wherein said buffer element has an amplifying factor of two.

6. A tap device as recited in claim 1 having a powered up state and a powered down state wherein an input impedance to said tap circuit is high relative to said network interconnection path in both said powered up and a powered down states.

7. A tap device comprising:
a first tap electrically connected to a first network interconnection path,
a second tap electrically connected to a second network interconnection path,
a buffer amplifier having an input end and an output end, and
an isolation transformer having an input side and an output side, said input side connected to said first and second taps and said output side connected to said input end of said buffer amplifier.

8. A tap device as recited in claim 7 wherein said output end of said buffer is connected to a monitoring path.

9. A tap device as recited in claim 8 wherein said monitoring path is connected to a processor and display device that collects and analyzes data present on said monitoring path.

10. A tap device as recited in claim 8 wherein said output end of said buffer is connected to a voltage divider circuit that is matched to an impedance of said monitoring path.

11. A tap device as recited in claim 7 and further comprising a plurality of first and second taps, and a respective plurality of buffer amplifiers and isolation transformers, wherein each one of said output ends of said buffer amplifier are aggregated onto a single monitoring path.

12. A tap device as recited in claim 7 wherein said isolation transformer is a one to one transformer.

13. A tap device as recited in claim 7 wherein said buffer amplifier has an amplifying factor of two.

14. A tap device as recited in claim 7 wherein said isolation transformer converts a differential signal present on said first and second interconnection paths to a single ended signal for presentation to said buffer amplifier.

15. A tap device as recited in claim 7 having a powered up state and a powered down state wherein an input impedance to said tap circuit is high relative to said network interconnection path in both said powered up and said powered down states.

16. An apparatus for eavesdropping onto a data network comprising:
an input port having at least first and second input interconnection points,
an output port having at least first and second output interconnection points,
first and second interconnection paths between said first input interconnection point and said first output interconnection point, and said second input interconnection point and said second output interconnection point, respectively,
a first tap electrically connected to said first interconnection path,
a second tap electrically connected to said second interconnection path,
an isolation transformer having first and second primary winding ends and first and second secondary winding ends, said first tap connected to said first primary winding end and said second tap connected to said second primary winding end,
a buffer having positive and negative input connections and an output end, said first secondary winding end connected to said positive input connection and said second secondary winding end connected to said negative input connection.

17. An apparatus for eavesdropping as recited in claim 16 wherein said output end of said buffer is connected to a monitoring path.

18. An apparatus for eavesdropping as recited in claim 17 wherein said monitoring path is connected to a processor and display device that collects an analyzes data present on said monitoring path.

19. An apparatus for eavesdropping as recited in claim 17 wherein said output end of said buffer is connected to a voltage divider circuit that is matched to an impedance of said monitoring path.

20. An apparatus for eavesdropping as recited in claim 16 and further comprising a plurality of first and second taps, and a respective plurality of buffers and isolation transformers, wherein each one of said output ends of said buffer amplifier are aggregated onto a single monitoring path.

21. An apparatus for eavesdropping as recited in claim 16 wherein said isolation transformer is a one to one transformer.

22. An apparatus for eavesdropping as recited in claim 16 wherein said buffer amplifier has an amplifying factor of two.

23. An apparatus for eavesdropping as recited in claim 16 wherein said isolation transformer converts a differential signal present on said first and second interconnection paths to a single ended signal for presentation to said buffer amplifier.

24. A method for insuring uninterrupted operation of a monitored network comprising the steps of:
connecting a first tap device to the monitored network, the first tap device comprising a chassis, a power supply, a rear transition module and an aggregator,
monitoring said network through said first tap device,
removing power from said first tap device,
removing said rear transition module from said first tap device,
installing said rear transition module into a second tap device, said second tap device comprising a chassis, a power supply and an aggregator,
powering said second tap device, and
monitoring said network through said second tap device.

25. A method as recited in claim 24 wherein said rear transition module comprises a tap interface having a sufficiently high impedance relative to a network interconnection path in both a powered-up and powered-down state so that data communication on said monitored network is unaffected transitioned between said powered-up and said powered-down states.

26. A method for programming a network switch to perform an aggregation function comprising the steps of:
disabling a spanning bridge tree protocol, a generic attribute registration protocol VLAN registration protocol, and a generic attribute registration protocol multicast registration protocol,
defining virtual local area networks as one or more switch ports with a high speed port, and
turning a switch learning mode off.

27. A method for programming a network switch as recited in claim 26 wherein said switch ports are 100BaseT ports and said high speed port is a Gigabit port.
